(19) United States
(12) Patent Application Publication
(10) Pub. No.: US 2016/0336467 A1
(43) Pub. Date: Nov. 17, 2016

(54) HIGH-EFFICIENCY FLEXIBLE PHOTOVOLTAIC FILM, MANUFACTURING PROCESS AND USE

(71) Applicant: SOLAR CLOTH SYSTEM, Mandelieu La Napoule (FR)

(72) Inventor: Alain JANET, MANDELIEU LA NAPOULE (FR)

(21) Appl. No.: 15/112,969

(22) PCT Filed: Jan. 16, 2015
(86) PCT No.: PCT/EP2015/050753

§ 371 Date: Jul. 20, 2016

(30) Foreign Application Priority Data
Jan. 21, 2014 (FR) 1400114

(51) Int. Cl. H01L 31/048; H01L 31/0392; H01L 31/054

(52) U.S. Cl. CPC H01L 31/048; H01L 31/0543; H01L 31/0481; H01L 31/03926

(57) ABSTRACT

A new-generation photovoltaic flexible film offering high efficiency results from the combination of an ultra-thin and very flexible photovoltaic film with a very thin, antireflection, prismatic film absorbing energy from solar radiation and righting the angle of the solar rays is provided. The process of the invention allows encasement of the photovoltaic modules and the prismatic film by an assembly of flexible polymer thermoplastic thin films and resinless thermofusion in vacuo.

### FIELD OF THE INVENTION

The invention is in the field of photovoltaic films and in particular relates to a high-efficiency photovoltaic flexible film, a process for obtaining such a film and its use in diverse devices.

### PRIOR ART

Current environmental and economic issues, namely among others, increasing energy prices, the shortage of hydrocarbon resources, the impact of CO2 emissions on global warming, or else concerns related to energy independence, are heightening current interest in renewable energies such as wind power or photovoltaics which can contribute to the energy mix and to economic development.

Photovoltaic solar technologies which convert solar energy into electricity by utilizing the photovoltaic effect constitute a pathway of interest for energy-related transition.

However, the cost of photovoltaic cells is still too high and their efficiencies are still too low to constitute a heavily adopted solution for diverse applications in regard to electricity produced in a centralized manner through conventional pathways, namely nuclear, thermal or hydraulic.

The need therefore exists for a solution having increased photovoltaic efficiency making it possible to address multiple applications, both industrial and individual.

### SUMMARY OF THE INVENTION

An object of the present invention is to propose a new-generation photovoltaic flexible film offering high efficiency.

Another object of the present invention is directed to a process for obtaining a high-efficiency photovoltaic flexible film.

Advantageously, the implementation of the photovoltaic flexible film of the present invention does not require a heavy and expensive support, thus allowing an overall reduction in usage costs.

According to one embodiment, the process of the invention makes it possible to combine flexible photovoltaic films with prismatic films which right the angle of the solar rays to obtain flexible and lightweight photovoltaic films of high efficiency.

Advantageously, by virtue of its low weight and its ease of manipulation, the photovoltaic flexible film of the present invention can be used with load-bearing structures of the roof type that cannot support significant weights.

Advantageously, the flexible film obtained can be wound and unwound manually and/or mechanically.

Advantageously, the invention will also find applications in market segments such as:
that of isolated sites with diverse applications related to transport, to street furniture, to the outdoors or for car park canopies for example;
that of sites connected to the grid especially for integration into roofs which cannot support the weight of conventional modules.

Still advantageously, the film obtained by the process of the present invention allows photovoltaic production even when the angle of incidence of the light rays decreases, thus improving the efficiency of the installations.

Thus, to obtain a multilayer photovoltaic film having at least one prismatic layer and a photovoltaic layer, the process of the invention comprises at least one step of vacuum encapsulation of the photovoltaic layer between two flexible polymer films and a step of thermofusion of said multilayers, the prismatic layer containing nano-prisms making it possible to right the angle of the light rays.

In one embodiment, the polymer films are copolymers selected from the group of ethylene-acrylic acids (EAAs) or ethylene-methyl acrylates (EMAs).

In a variant, the polymer films are nano films having a mean thickness of from 40 to 50 micrometers.

Advantageously, the thermofusion step is carried out without resin in an enclosed oven.

Still advantageously, the thermofusion step is carried out over a temperature range lying between 95° and 180° centigrade.

In one embodiment, the photovoltaic layer consists of plate-like photovoltaic cells.

Advantageously, the photovoltaic cells are chosen from the group of cells of Copper, Indium, Gallium, Selenium (CIGS) mixture type, of Cadmium Telluride (CdTe) or of Selenium (CdS) type, of printable or non-printable organic (OPV) type, or else of “Dye-Sensitized Solar Cell” (DSSC, DSC) type.

In a variant, the photovoltaic layer moreover comprises a network of electrical conductors.

In another embodiment, the prismatic layer consists of a transparent very thin prismatic film having surface micro-grooves.

The invention also relates to a multilayer photovoltaic film comprising at least one prismatic upper layer and a photovoltaic intermediate layer, the film being characterized in that the photovoltaic layer is encapsulated between two flexible polymer films.

In an embodiment, the multilayer photovoltaic film comprises a lower layer forming a reinforcement thickness consisting of a textile meshwork exhibiting a fiber angulation of from 0° to 90°.

In a variant, the lower layer moreover comprises a film made of polyester or polyvinyl fluoride.

In another variant, the lower layer moreover comprises a film made of synthetic taffeta loosely woven with polyester fibers.

The invention relates moreover to the use of the high-efficiency photovoltaic flexible film obtained according to the process of the invention, in particular, its use on a structure of roof or sail type.

### DESCRIPTION OF THE FIGURES

Various aspects and advantages of the invention will become apparent in support of the description of a preferred but none limiting mode of implementation of the invention, with reference to the figures hereinbelow:

FIGS. 1a and 1b show respectively a sectional view of the structure of the high-efficiency photovoltaic flexible film of the present invention according to two embodiments;

FIG. 2 illustrates the main steps of the encasement process of the invention;

FIG. 3 shows various structures making it possible to use the invention advantageously; and

FIGS. 4a to 4e illustrate the optical function produced by the high-efficiency photovoltaic film of the present invention.

### DETAILED DESCRIPTION OF THE INVENTION

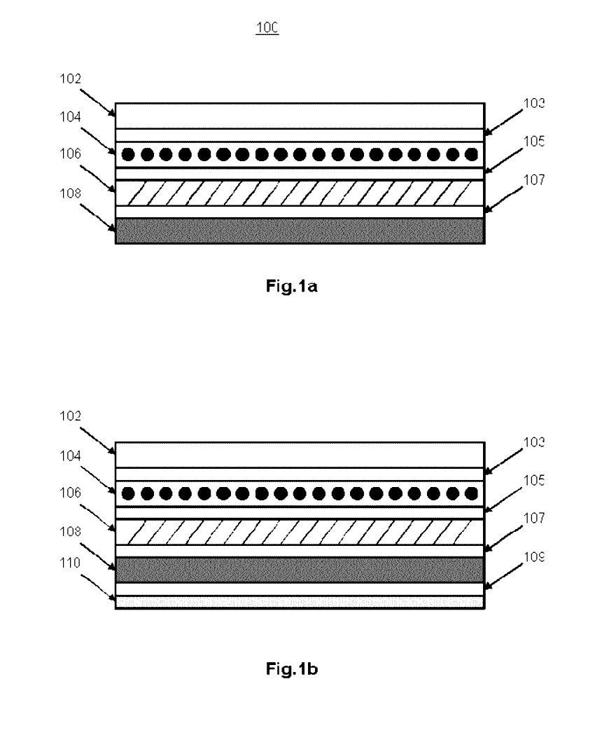

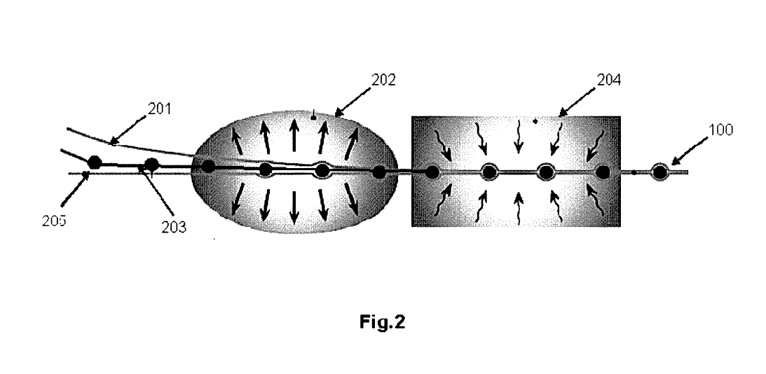

Reference is now made to FIGS. 1a and 1b and to FIG. 2. FIG. 1a shows a sectional view of a first structure of the high-efficiency photovoltaic flexible film (100) of the present invention, obtained according to the process illustrated schematically in FIG. 2, and FIG. 1b shows a sectional view of a variant of the structure of FIG. 1a.

The film (100) is multilayer and composed mainly of an upper or top layer (102) constituting the prismatic layer of the film, of a lower or bottom layer (106, 107, 108, 109 or 110) constituting a reinforcement and of an intermediate layer (104) constituting the photovoltaic layer.

The top layer (102) consists of a very thin prismatic film having a thickness of substantially between 20 and 70 micrometers.

In a variant, the prismatic film can be structured with surface micro-grooves known as “riblets effect” and constituting a protective barrier.

In a preferential embodiment, the prismatic film is transparent, antireflection, antishock and very stable to UV. It absorbs the energy from solar radiation and contains nano-prisms to right the angle of the light rays. Such a film which can be a film available off-the-shelf improves the daily optimum exposure time and thus increases the yield of the light-absorbing photovoltaic film placed as bottom layer.

The intermediate layer comprises a film of photovoltaic cells (104). The cells can be plate-like (known as “shingle”) or slate-like. In a preferential embodiment, the photovoltaic cells are chosen from the group of cells of Copper, Indium, Gallium, Selenium (CIGS) mixture type, of Cadmium Telluride (CdTe) or of Selenium (CdS) type, of printable or non-printable organic (OPV) type, or else of “Dye-Sensitized Solar Cell” (DSSC, DSC) type.

The thickness of the film of photovoltaic cells preferably lies between 5 to 100 micrometers. Such a film can be a film available off-the-shelf.

The intermediate layer moreover comprises a network of electrical conductors as well as a connection technology making it possible to transport the harvested energy. According to the variants, the electrical conductors are circuits made of copper or of silver clay for example. In a variant embodiment, the network of electrical conductors comprises rechargeable batteries and a charge regulating device, in particular for powering “LEDs” or “OLEDs” positioned under the multilayer film.

As shown in FIG. 1a or 1b, the photovoltaic intermediate layer is encapsulated between two copolymer inter-layers (103, 105). In a preferential embodiment, the encapsulation material consists of a copolymer selected from the group of ethylene-acrylic acids (EAAs) or ethylene-methyl acrylates (EMAs) to allow a solid, durable and leaktight transparent matrix bond between the various films and components of the structure (100). According to the variant embodiments, the inter-layers are nano films having a mean thickness of from 40 to 50 micrometers.

According to the process of the invention, the multilayers of the structure of the film are laminated by fusion of thermoplastic polymer films. The thermofusion (202, 204) is carried out in vacuo, without resin, over a temperature range of from 95° to 180° centigrade.

The lower or bottom layer (106, 107, 108, 109, 110) comprises a reinforcement thickness (106) constituting a textile meshwork exhibiting a fiber angulation of from 0° to 90°. In a preferential manner, the mesh consists of fibers chosen from the group of fibers of glass or polyester terephthalate (PET) type or aromatic polyamide (Aramid) or carbon or Poly(p-phenylene-2,6-benzobisoxazole) (PBO) type known by the brand name Zylon®, or Ultra-high-molecular-weight polyethylene (UHMWPE) type also known by the name high-modulus polyethylene (HMPE), or liquid-crystal polymer (LCP) type known under the brand name Vectran®, or else of multifilament polyolefin type known under the brand name Innegra®, or made of basalt fiber. The examples given of the fibers for the reinforcement mesh are not limiting and any other material making it possible to obtain high mechanical stability can be considered. The reinforcement mesh makes it possible advantageously to resist tensile and buffeting stresses due to the wind, mainly when the film is used outdoors or for use prone to deformations, breakages or delamination.

According to variant embodiments, the reinforcement mesh can be supplemented with a complementary film (108) which is laminated by fusion of a thermoplastic polymer film (107) in the course of the process for obtaining the final structure (100).

In a preferential manner, the complementary film (108) is a polyester film or a Tedlar® film particularly suitable for tropical regions, and making it possible to ensure leaktightness of the lower part of the structure (100).

In another variant embodiment such as shown in FIG. 1b, a loosely woven synthetic taffeta (110) is added to the complementary film. In a preferential manner, the taffeta is made of polyester fibers or Dyneema® fibers.

In one implementation of use, a binding tape is sewn onto the taffeta to take eyes and fit a tape or taped cord which affords significant resistance to UV, to impacts, to rubbing such as chafing, and to tearing, while protecting the leaktight Polyester film situated above.

The two variants described of the structure of the high-efficiency photovoltaic flexible film of the invention are obtained according to an innovative process whose main steps (202, 204) are schematically illustrated in FIG. 2. The process thus consists in integrating, and then encapsulating at least two nano films (102, 104) in a multi-layer structure whose layers are laminated by fusion of thermoplastic polymer films. The thermofusion is carried out without resin, in vacuo in an enclosed oven, or alternatively between two heating zones (plates, blankets) in a temperature range lying between 95° and 180° centigrade.

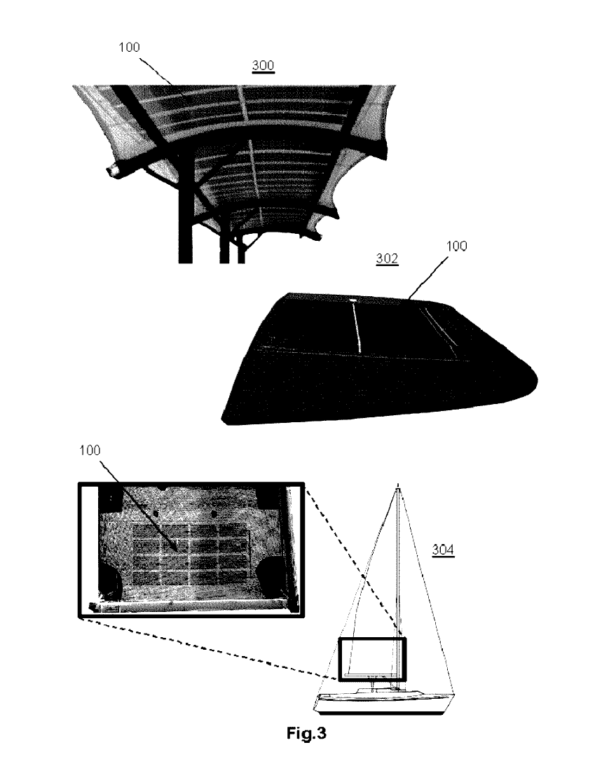

FIG. 3 shows examples of using the high-efficiency photovoltaic flexible film (100) of the invention as a car park canopy (300), as a boat bimini (302) or integrated into boat sails (304).

The inventor has estimated that a canopy used to cover for example a car park of some twenty or so cars echelon style, representing about 400 m², could receive of the order of 300 m² of the photovoltaic flexible film of the invention, i.e. of the order of 75% of the total area. Moreover, such a 300 m² car park canopy would produce of the order of 31.5 kW at 12 volts or 28 kW at 220 volts, this corresponding substantially to the total electrical consumption of a 30 m ship.

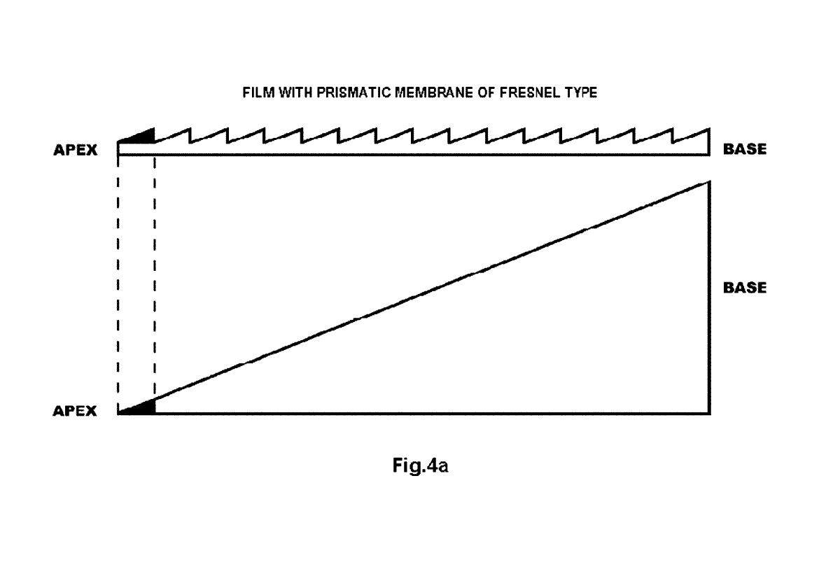

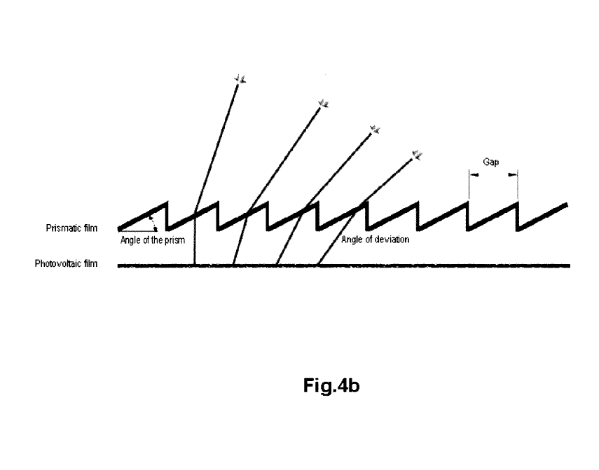

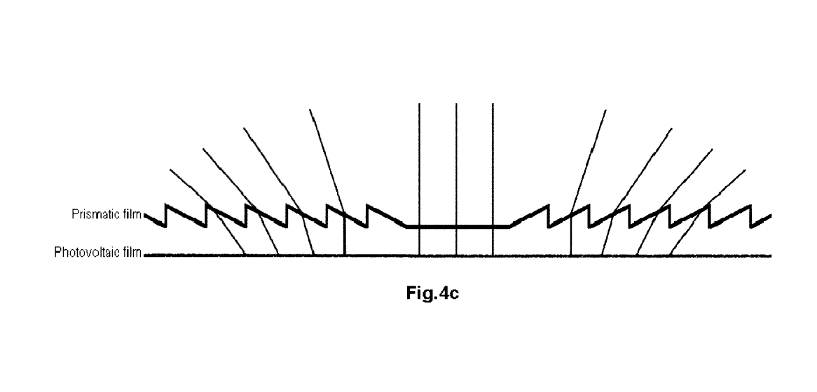

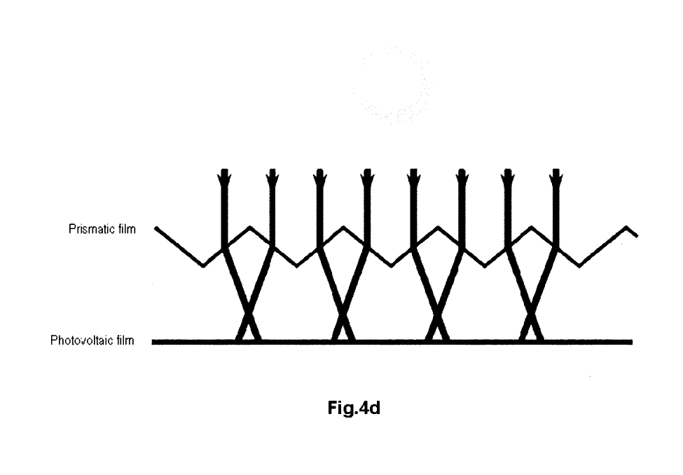

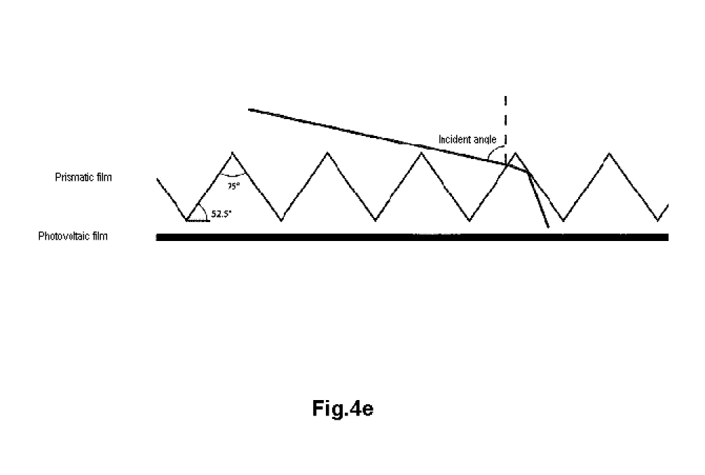

FIGS. 4a to 4e illustrate the optical function produced by the high-efficiency photovoltaic film of the present invention. Indeed, the prismatic layer used in the present invention exhibits characteristics for righting the angle of the solar rays. It is aimed at solving the problem of having photovoltaic films which are productive and efficient, whatever the sunshine, whatever the angle of the light rays, in contradistinction to the prismatic films known to the person skilled in the art which are used as protective layers or as barriers.

FIG. 4a shows a so-called Fresnel prism comprising narrow parallel bands of prism with one and the same vertex angle as the single base prism where “the angle of refraction is independent of the thickness of the prism”.

Such films are in a preferential manner fabricated from lightweight polymers.

As illustrated in FIG. 4b, the simple prismatic films have a sawtooth structure and deviate the light rays according to an angle determined by the geometry of the prism.

When a Fresnel lens, in the form of parallel bands, consists of a slender flexible material (polymer) comprising grooves in a surface, the resulting so-called “prismatic film” lens membrane can be applied to a plane or curved optical surface.

Advantageously, as illustrated in FIG. 4c, it is possible to combine one and the same symmetric profile with a series of simple prisms, in the form of parallel bands, as well as a center open to the direct radiation of the luminous source. This combination makes it possible to optimize the collecting of the light rays by deviating them to improve the efficiency of the photovoltaic receiver film.

Advantageously, as illustrated in FIGS. 4d and 4e, a hat-shaped prism can be used for the purposes of taking advantage of the symmetry of the entry diopters of the prisms making up the prismatic film and their refraction capabilities. The apex angles and the angles of inclination of the sides vary as a function of the deviations sought.

The person skilled in the art will understand that only a few examples of use are described, but that they are in no sense limiting and that the high-efficiency photovoltaic flexible film of the invention can be used in various environments on isolated or linked sites, for numerous and diverse applications such as use on camping, marquee or military tents, for clothing uses, for roofs or as flexible and pliable claddings, on an inclined plane such as for example on the sail of a listing boat, on street furniture such as bus shelters or vehicles to cite only a few exemplary applications. Moreover, minor variants can be introduced into the process without however impacting the final structure of the photovoltaic flexible film described which offers high efficiency.

1. A process for obtaining a multilayer photovoltaic film having at least one prismatic layer and a photovoltaic layer, the process comprising at least one step of vacuum encapsulation of the photovoltaic layer between two flexible polymer films and a step of thermofusion of said multilayers, the prismatic layer containing nano-prisms making it possible to right the angle of the light rays.

2. The process as claimed in claim 1, wherein the polymer films are copolymers selected from the group of ethylene-acrylic acids or ethylene-methyl acrylates.

3. The process as claimed in claim 1 wherein the polymer films are nano films having a mean thickness of from 40 to 50 micrometers.

4. The process as claimed in claim 1, wherein the thermofusion step is carried out without resin in an enclosed oven.

5. The process as claimed in claim 1, wherein the thermofusion step is carried out over a temperature range lying between 95° and 180° centigrade.

6. The process as claimed in claim 1, wherein the photovoltaic layer consists of plate-like or slate-like photovoltaic cells.

7. The process as claimed in claim 1, wherein the photovoltaic cells are chosen from the group of cells of Copper, Indium, Gallium, Selenium mixture type, of Cadmium Telluride or of Selenium type, of printable or non-printable organic type, or else of “Dye-Sensitized Solar Cell” type.

8. The process as claimed in claim 1, wherein the photovoltaic layer moreover comprises a network of electrical conductors.

9. The process as claimed in claim 1, wherein the prismatic layer consists of a transparent very thin prismatic film having surface micro-grooves.

10. A multilayer photovoltaic film comprising at least one prismatic upper layer and a photovoltaic intermediate layer, wherein the prismatic layer contains nano-prisms making it possible to right the angle of the light rays and the photovoltaic layer is encapsulated between two flexible polymer films.

11. The multilayer photovoltaic film as claimed in claim 10, moreover comprising a lower layer forming a reinforcement thickness consisting of a textile meshwork exhibiting a fiber angulation of from 0° to 90°.

12. The multilayer photovoltaic film as claimed in claim 11, where the lower layer moreover comprises complementary film made of polyester or polyvinyl fluoride.

13. The multilayer photovoltaic film as claimed in claim 12, where the complementary film moreover comprises a film of loosely woven synthetic taffeta made of polyester fibers.

14. The photovoltaic film as claimed in claim 10, obtained by a process comprising at least one step of vacuum encapsulation of the photovoltaic layer between two flexible polymer films and a step of thermofusion of said multilayers, the prismatic layer containing nano-prisms making it possible to right the angle of the light rays.

15. A structure of roof or wing type comprising a photovoltaic film obtained according to the process of claim 1.
